(19) United States
(12) Patent Application Publication
(10) Pub. No.: US 2026/0090378 A1
(43) Pub. Date: Mar. 26, 2026

(54) ELECTRONIC DEVICE AND METHOD FOR MANUFACTURING THE SAME

(71) Applicant: InnoLux Corporation, Miao-Li County (TW)

(72) Inventor: Po-Yun HSU, Miao-Li County (TW)

(73) Assignee: InnoLux Corporation, Miao-Li County (TW)

(21) Appl. No.: 19/326,686

(22) Filed: Sep. 11, 2025

Related U.S. Application Data
(60) Provisional application No. 63/698,572, filed on Sep. 25, 2024.

(30) Foreign Application Priority Data
May 23, 2025 (CN) 202510668591.8

(51) Int. Cl. H01L 23/373; H01L 21/48; H01L 23/00; H01L 23/538; H01L 25/065

(52) U.S. Cl. CPC H10W 40/25; H10W 42/121; H10W 70/05; H10W 70/611; H10W 90/00; H10W 90/401; H10W 74/15; H10W 90/724; H10W 90/733; H10W 90/734

(57) ABSTRACT

An electronic device includes a first substrate structure, a first circuit structure and a package structure. The first circuit structure is disposed on a surface of the first substrate structure, and the first circuit structure includes a first substructure. The package structure is disposed on the first circuit structure and electrically connected with the first circuit structure. The first substructure has a first coefficient of thermal expansion, the package structure has a second coefficient of thermal expansion, and a ratio of the second coefficient of thermal expansion to the first coefficient of thermal expansion is greater than or equal to 0.8 and less than or equal to 1.5.

### CROSS REFERENCE TO RELATED APPLICATION

This application claims the benefit of U.S. Provisional Application No. 63/698,572, filed on Sep. 25, 2024. The content of the application is incorporated herein by reference.

### BACKGROUND OF THE DISCLOSURE

### 1. Field of the Disclosure

The present disclosure relates to an electronic device and a method for manufacturing the same, and more particularly, to an electronic device which is beneficial for reducing warpage and a method for manufacturing the same.

### 2. Description of the Prior Art

In the field of integrated circuits, electronic devices may need to be configured with larger dimensions (e.g., larger areas) and more layers according to different applications and requirements. The aforementioned layers may include carriers used in the manufacturing process, substrate structures and redistribution layers as part of the final product. For example, using a large-area carrier in production is beneficial for increasing the output rate of packaging units or reducing manufacturing costs. However, when the dimension of the electronic device increases and the number of layers increases, the warpage degree of the electronic device also increases significantly, which may affect the yield of the electronic device.

### SUMMARY OF THE DISCLOSURE

According to an embodiment of the present disclosure, an electronic device includes a first substrate structure, a first circuit structure and a package structure. The first circuit structure is disposed on a surface of the first substrate structure, and the first circuit structure includes a first substructure. The package structure is disposed on the first circuit structure and electrically connected with the first circuit structure. The first substructure has a first coefficient of thermal expansion, the package structure has a second coefficient of thermal expansion, and a ratio of the second coefficient of thermal expansion to the first coefficient of thermal expansion is greater than or equal to 0.8 and less than or equal to 1.5.

According to another embodiment of the present disclosure, a method for manufacturing an electronic device includes steps as follows. A carrier is provided. A circuit structure is provided on the carrier, which includes steps as follows. A first substructure is provided on the carrier. The first substructure includes a first adjustment element. A warpage degree of the first substructure is calculated. A second substructure is provided on the first substructure, and whether to provide a second adjustment element in the second substructure is determined based on the warpage degree.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a three-dimensional schematic diagram showing an electronic device according to an embodiment of the present disclosure.

FIG. 2 is a cross-sectional schematic diagram of the electronic device shown in FIG. 1 taken along line A-A′.

FIG. 3 and FIG. 4 are cross-sectional schematic diagrams showing a method for manufacturing the electronic device shown in FIG. 2.

FIG. 5 is a cross-sectional schematic diagram of an electronic device according to another embodiment of the present disclosure.

FIG. 6 is a cross-sectional schematic diagram of an electronic device according to yet another embodiment of the present disclosure.

FIG. 7 is a cross-sectional schematic diagram of an electronic device according to yet another embodiment of the present disclosure.

FIG. 8 is a cross-sectional schematic diagram of an electronic device according to yet another embodiment of the present disclosure.

FIG. 9 is a flow chart illustrating steps of a method for manufacturing an electronic device according to yet another embodiment of the present disclosure.

FIG. 10 is a cross-sectional schematic diagram of an electronic device according to yet another embodiment of the present disclosure.

### DETAILED DESCRIPTION

The present disclosure may be understood by reference to the following detailed description, taken in conjunction with the drawings as described below. Wherever possible, the same or similar parts in the drawings and descriptions are represented by the same reference numeral.

Certain terms are used throughout the description and following claims to refer to particular components. As one skilled in the art will understand, electronic equipment manufacturers may refer to a component by different names. This document does not intend to distinguish between components that differ in name but not function. In the following description and in the claims, the terms “include/comprise” and “have” are used in an open-ended fashion, and thus should be interpreted to mean “include, but not limited to . . . ”.

In the present disclosure, the directional terms, such as “on/up/above”, “down/below”, “front”, “rear/back”, “left”, “right”, etc., are only directions referring to the drawings. Therefore, the directional terms are used for explaining and not used for limiting the present disclosure. Regarding the drawings, the drawings show the general characteristics of methods, structures, and/or materials used in specific embodiments. However, the drawings should not be construed as defining or limiting the scope or properties encompassed by these embodiments. For example, for clarity, the relative size, thickness, and position of each layer, each area, and/or each structure may be reduced or enlarged.

In the present disclosure, the intervening structure may be a single-layer or multi-layer physical structure or a non-physical structure, and the present disclosure is not limited thereto. In the present disclosure, when a certain structure is disposed “on/above” other structures, it may refer that the certain structure is “directly” disposed on/above the other structures, or the certain structure is “indirectly” disposed on/above the other structures, i.e., at least one structure is disposed between the certain structure and the other structures.

In the present disclosure, the term “connection” may include physical connection or electrical connection, and may include direct contact or indirect contact.

The terms “equal”, “identical/the same”, or “substantially/approximately” mentioned in this document generally mean being within 20% of a given value or range, or being within 10%, 5%, or 0.5% of the given value or range.

Furthermore, if a first direction is perpendicular or “substantially” perpendicular to a second direction, then an angle between the first direction and the second direction may be between 80 degrees to 100 degrees; if the first direction is parallel or “substantially” parallel to the second direction, an angle between the first direction and the second direction may be between 0 degree to 10 degrees.

Although ordinal numbers such as “first”, “second”, etc., may be used to describe elements in the description and the claims, it does not imply and represent that there have other previous ordinal number. The ordinal numbers do not represent the order of the elements or the manufacturing order of the elements. The ordinal numbers are only used for discriminate an element with a certain designation from another element with the same designation. The claims and the description may not use the same terms. Accordingly, a first element in the description may be a second element in the claims.

In addition, the term “a given range is from a first value to the second value” or “a given range falls within a range from a first value to a second value” refers that the given range includes the first value, the second value and other values therebetween.

In the present disclosure, “an element surrounds another element” may refer that in a cross-sectional view, the element at least contacts a side surface of the another element.

In the present disclosure, the process for manufacturing the electronic device may be applied to a wafer-level package (WLP) process or a panel-level package (PLP) process, and may be a chip first process or a chip last (i.e., RDL first) process.

The electronic device of the present disclosure may be applied to a power module, a semiconductor package device, a display device, a light emitting device, a backlight device, an antenna device, a sensing device or a tiled device, but not limited thereto. The electronic units of the electronic device may include passive elements and active elements, such as semiconductor structure, capacitors, resistors, inductors, diodes and transistors. The electronic device may have peripheral systems, such as a driving system, a control system and a light system for supporting the display device, the antenna device, the wearable device or the vehicle-mounted device (for example, including car windshields). The electronic device may include packaging devices, such as high bandwidth memory (HBM) packages, system on a chip (SoC), system in a package (SiP), antenna in package (AiP), co-packaged optics (CPO), or a combination thereof, but not limited thereto.

In the present disclosure, the redistribution layer structure may be electrically connected with each of the electronic units through bonding elements, such as bumps, solder balls or pads. The redistribution layer structure may include at least one conductive layer and at least one insulating layer. The redistribution layer structure may be configured to redistribute circuits and/or further increase the circuit fan-out area, or different electronic elements may be electrically connected with each other through the redistribution layer structure. The method of forming the redistribution layer structure may include providing a stack of at least one insulating layer and at least one conductive layer, and may include processes such as photolithography, etching, surface treatment, laser and electroplating. The surface treatment may include roughening the surface of the insulating layer or the surface of the conductive layer to improve the bonding ability thereof. Alternatively, the redistribution layer structure may serve as a substrate for routing electrical interface between one connection and another connection. The purpose of the redistribution layer structure is to fan out the connection to allow the connection to have a wider pitch or to redistribute the connection to another connection with a different pitch.

In the present disclosure, the term “modification” may refer to a portion whose mechanical strength is reduced after being modified.

In the present disclosure, it should be understood that a depth, a thickness, a width or a height of each element, or a spaced distance or a distance between elements may be measured by an optical microscopy (OM), a scanning electron microscope (SEM), a film thickness profiler (α-step), or other suitable methods. In some embodiments, a cross-sectional image including elements to be measured can be obtained by the SEM, and the depth, the thickness, the width or the height of each element, or the spaced distance or the distance between elements can be measured thereby.

In the present disclosure, the definition of roughness may be as follow. For example, a surface is observed by the SEM or a transmission electron microscope (TEM). When a distance difference of 0.15 μm to 1 μm is between the crest point and the trough point of the surface undulation on the surface to be observed, the surface to be observed is determined to be rough. In the present disclosure, the determination of roughness to observe the surface undulation at a same appropriate magnification, and the undulation degree are compared by taking a unit length (such as 10 μm). Herein, “appropriate magnification” may refer that at least 10 undulating peaks can be seen on at least one surface under the field of view of the magnification.

It should be noted that the technical features in different embodiments described in the following can be replaced, recombined, or mixed with one another to constitute another embodiment without departing from the spirit of the present disclosure.

It can be understood that these terms, such as those defined in commonly used dictionaries, should be interpreted as having meanings consistent with the background or context of the related technology and the present disclosure, and should not be interpreted in an idealized or overly formal manner, unless otherwise specified in the disclosed embodiments.

In the present disclosure, the numbers of elements in the electronic devices shown in the following drawings, such as package structures, electronic units, circuit structures, substructures, substrate structures, through holes, conductive elements, pads, bonding elements and adjustment element, are only for illustration and are not limited thereby.

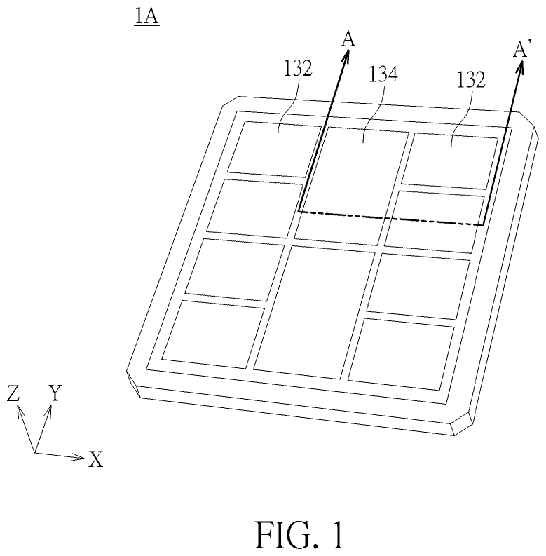

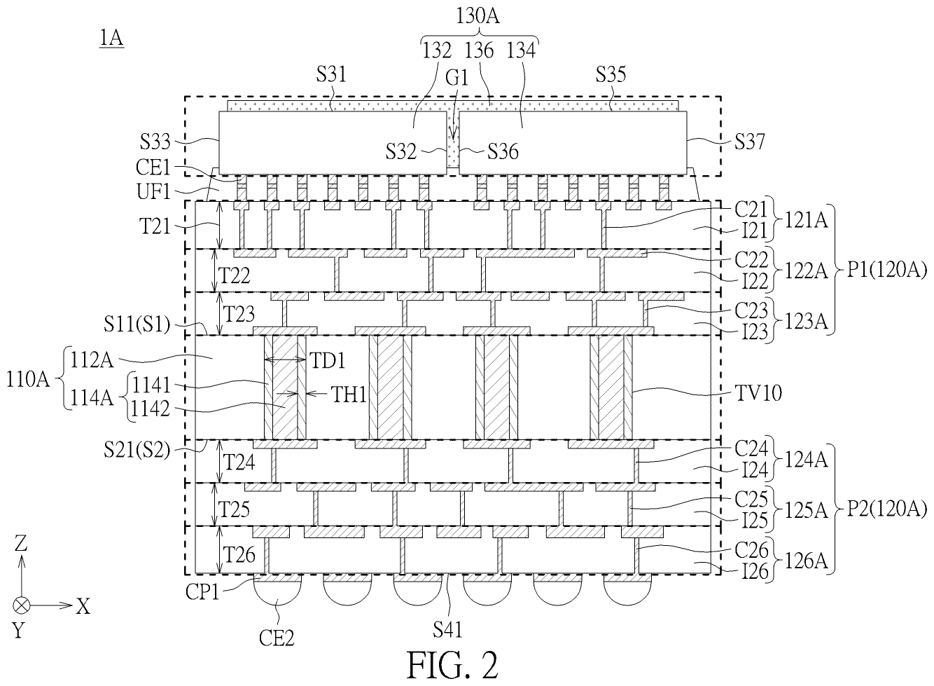

Please refer to FIG. 1 and FIG. 2. FIG. 1 is a three-dimensional schematic diagram showing an electronic device 1A according to an embodiment of the present disclosure. FIG. 2 is a cross-sectional schematic diagram of the electronic device 1A shown in FIG. 1 taken along line A-A′. In FIG. 1 and FIG. 2, the electronic device 1A is a package device as an example. The electronic device 1A includes a substrate structure 110A, a circuit structure 120A, and a package structure 130A. The circuit structure 120A is disposed on the surface S1 and the surface S2 of the substrate structure 110A. The circuit structure 120A may include at least one substructure. Herein, the circuit structure 120A includes six substructures as an example, namely, substructures 121A˜126A. The number of substructures in the circuit structure 120A may be adjusted according to actual needs. The package structure 130A is disposed on the circuit structure 120A and is electrically connected with the circuit structure 120A. Each of the substructures 121A˜126A has a coefficient of thermal expansion, the package structure 130A has a coefficient of thermal expansion, and a ratio of the coefficient of thermal expansion of the package structure 130A to the coefficient of thermal expansion of at least one of the substructures 121A˜126A is greater than or equal to 0.8 and less than or equal to 1.5. Thereby, it is beneficial to improve the matching degree of the coefficient of thermal expansion of the package structure 130A and the coefficient of thermal expansion of the circuit structure 120A, which is beneficial to reduce the warpage degree of electronic device 1A.

In some embodiments, the ratio of the coefficient of thermal expansion of the package structure 130A to the coefficient of thermal expansion of any of the substructures 121A˜126A is greater than or equal to 0.8 and less than or equal to 1.5. Thereby, it is beneficial to further reduce the warpage degree of the electronic device 1A.

The substrate structure 110A may have a coefficient of thermal expansion, and a ratio of the coefficient of thermal expansion of the package structure 130A to the coefficient of thermal expansion of the substrate structure 110A may be greater than or equal to 0.8 and less than or equal to 1.5. Thereby, it is beneficial to further reduce the warpage degree of the electronic device 1A.

Specifically, the substrate structure 110A may include a base layer 112A and a conductive element 114A. The base layer 112A may have a through hole TV10. The conductive element 114A may be disposed in the through hole TV10. Herein, the base layer 112A has a plurality of through holes TV10 as an example. The number of the through holes TV10 in the base layer 112A may be adjusted according to actual needs. Each of the through holes TV10A is disposed with a conductive element 114A, so that the first portion P1 of the circuit structure 120A located above the substrate structure 110A and the second portion P2 of the circuit structure 120A located below the substrate structure 110A can be electrically connected through the conductive elements 114A.

In some embodiments, in a direction (e.g., the direction X) perpendicular to the normal direction (i.e., parallel to the direction Z), the conductive element 114A may include a buffer layer 1141 and a conductive layer 1142. The buffer layer 1141 may be disposed between the conductive layer 1142 and the base layer 112A. The buffer layer 1141 is disposed on the hole wall of the through hole TV10 and surrounds the conductive layer 1142. With the buffer layer 1141, it is beneficial to reduce the probability of microcracks in the base layer 112A, but not limited thereto. In some embodiments, the conductive element 114A may not include the buffer layer 1141, but only includes the conductive layer 1142. Herein, the conductive layer 1142 is a single-layer structure as an example. In some embodiments, the conductive layer 1142 may be a multi-layer structure. For example, the conductive layer 1142 may further include a seed layer (not shown) and/or a barrier layer (not shown). With the conductive layer 1142 including different metals, the coefficient of thermal expansion of the conductive layer 1142 can be further adjusted, so as to adjust the coefficient of thermal expansion of the substrate structure 110A.

The material of the base layer 112A may include glass, bismaleimide-triazine (BT) resin, flame retardant 4 (FR4), silicon, other suitable materials or a combination thereof.

The toughness of the buffer layer 1141 may be 0.1 kJ/m² to 100 kJ/m². The material of the buffer layer 1141 may include polyimide (PI) resin, parylene, benzocyclobutene (BCB), epoxy, polycarbonate (PC), polyethylene terephthalate (PET), polyethylene naphthalate (PEN), silicon-containing compounds or a combination thereof. In some embodiments, the thickness TH1 of the buffer layer 1141 may be 0.01 μm to 10 μm. The aforementioned thickness TH1 of the buffer layer 1141 may refer to the thickness of the buffer layer 1141 in the horizontal direction (e.g., the direction X) on the hole wall of the through hole TV10. In some embodiments, a ratio of the thickness TH1 of the buffer layer 1141 to the diameter TD1 of the through hole TV10 may be 0.02 to 0.2.

A material of the conductive layer 1142 may include titanium, iron, aluminum, copper, nickel, tungsten, gold, platinum, other suitable materials or a combination thereof. A material of the seed layer may include titanium, tungsten, nickel, other suitable materials or a combination thereof. According to an embodiment, the seed layer may include titanium copper or titanium nitride. A material of the barrier layer may include titanium (Ti), tantalum (Ta), copper or a combination thereof.

The circuit structure 120A may include a redistribution layer (RDL) structure. Herein, the circuit structure 120A includes a first portion P1 and a second portion P2 as an example, the first portion P1 and the second portion P2 are respectively redistribution layer structures, and the first portion P1 and the second portion P2 are disposed on opposite two sides of the substrate structure 110A. The first portion P1 is disposed on the surface S1 of the substrate structure 110A and is located above the substrate structure 110A. The second portion P2 is disposed on the surface S2 of the substrate structure 110A and is located below the substrate structure 110A. The base layer 112A has a normal direction (e.g., parallel to the direction Z), and the base layer 112A includes the surface S1 and the surface S2 disposed opposite to each other in the normal direction. The first portion P1 may include substructures 121A˜123A from top to bottom in the normal direction (e.g., parallel to the direction Z), and the second portion P2 may include substructures 124A˜126A from top to bottom in the normal direction. The circuit structure 120A may further include a plurality of pads CP1 disposed on the surface S41 of the substructure 126A and electrically connected with the conductive layer C26 of the substructure 126A.

The substructure 121A may include an insulating layer I21 and a conductive layer C21. The conductive layer C21 is disposed in the insulating layer I21. That is, in a cross-sectional schematic diagram, the insulating layer I21 contacts the side of the conductive layer C21. In the substructure 121A, the content (or the volume ratio) of the conductive layer C21 may range from 2 volume percent to 55 volume percent. The substructure 122A may include an insulating layer I22 and a conductive layer C22. The conductive layer C22 is disposed in the insulating layer I22, and the insulating layer I22 surrounds the conductive layer C22. In the substructure 122A, the content of the conductive layer C22 may range from 2 volume percent to 55 volume percent. The substructure 123A may include an insulating layer I23 and a conductive layer C23. The conductive layer C23 is disposed in the insulating layer I23, and the insulating layer I23 surrounds the conductive layer C23. In the substructure 123A, the content of the conductive layer C23 may range from 2 volume percent to 55 volume percent. The substructure 124A may include an insulating layer I24 and a conductive layer C24. The conductive layer C24 is disposed in the insulating layer I24, and the insulating layer I24 surrounds the conductive layer C24. In the substructure 124A, the content of the conductive layer C24 may range from 2 volume percent to 55 volume percent. The substructure 125A may include an insulating layer I25 and a conductive layer C25. The conductive layer C25 is disposed in the insulating layer I25, and the insulating layer I25 surrounds the conductive layer C25. In the substructure 125A, the content of the conductive layer C25 may range from 2 volume percent to 55 volume percent. The substructure 126A may include an insulating layer I26 and a conductive layer C26. The conductive layer C26 is disposed in the insulating layer I26, and the insulating layer I26 surrounds the conductive layer C26. In the substructure 126A, the content of the conductive layer C26 may range from 2 volume percent to 55 volume percent. In the present disclosure, “the content of the conductive layer” may be measured by an optical detection instrument such as an X-ray device to obtain the size or volume of the conductive layer in each film layer.

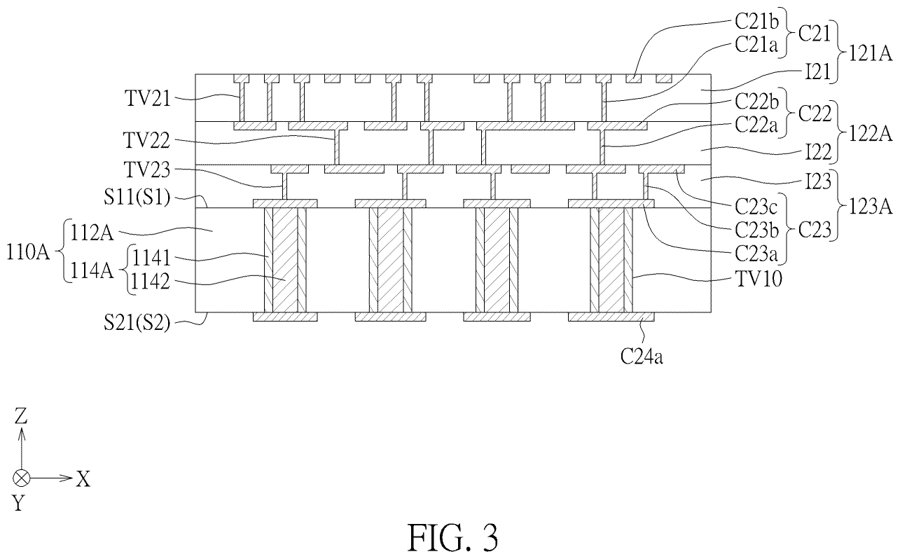

In some embodiments, the sizes (e.g., width and/or thickness) of the conductive layers C21˜C26 may be configured to increase gradually in a direction from the package structure 130A toward away from the package structure 130A. That is, the closer it is to the package structure 130A, the smaller the size. The sizes of the conductive layers C21˜C26 can be compared with the lengths of the corresponding parts of the conductive layers C21˜C26 in a direction. For example, the thickness of the pads of the conductive layers C21˜C26 are configured to increase gradually in a direction from the package structure 130A toward away from the package structure 130A (i.e., opposite to the direction Z). That is, in FIG. 3, the thickness of the pad C21b is less than the thickness of the pad C22b, the thickness of the pad C22b is less than the thickness of the pad C23c, and the thickness of the pad C23c is less than the thickness of the pad C23a. The aforementioned thickness may be the maximum length of the pad in the vertical direction (e.g., the direction Z). The substructure 121A closer to the package structure 130A is arranged with a conductive layer C21 with a smaller size, which is beneficial to increase the number of I/O (input/out-put) of the electronic unit 132 and the electronic unit 134, so that the I/O density of the electronic device 1A can be increased.

The insulating layers I21˜I26 may independently include an organic material or an inorganic material.

Each of the conductive layers C21˜C26 and the pad CP1 is a single-layer structure as an example. The conductive layers C21˜C26 and the pad CP1 may be similar with the conductive layer 1142. According to an embodiment of the present disclosure, The conductive layers C21˜C26 and the pad CP1 may include copper. In other embodiments, the conductive layers C21˜C26 and the pad CP1 may be a multi-layer structure. For example, each of the conductive layers C21˜C26 and the pad CP1 may optionally further include a seed layer (not shown) and/or a barrier layer (not shown). For The seed layer and the barrier layer, references may be made to the relevant description above.

In some embodiments, in the circuit structure 120A, the thickness T21 of the insulating layer I21, the thickness T22 of the insulating layer I22, the thickness T23 of the insulating layer I23, the thickness T24 of the insulating layer I24, the thickness T25 of the insulating layer I25 and the thickness T26 of the insulating layer I26 may be greater than the thickness TH1 of the buffer layer 1141. The aforementioned thicknesses T21˜T26 may be the maximum lengths of the insulating layers I21˜I26 in the vertical direction (e.g., the direction Z), respectively. The aforementioned thicknesses T21˜T26 may be 1 μm to 25 μm, 3 μm to 20 μm or 5 μm to 15 μm, and the thicknesses T21˜T26 may be independently the same or different.

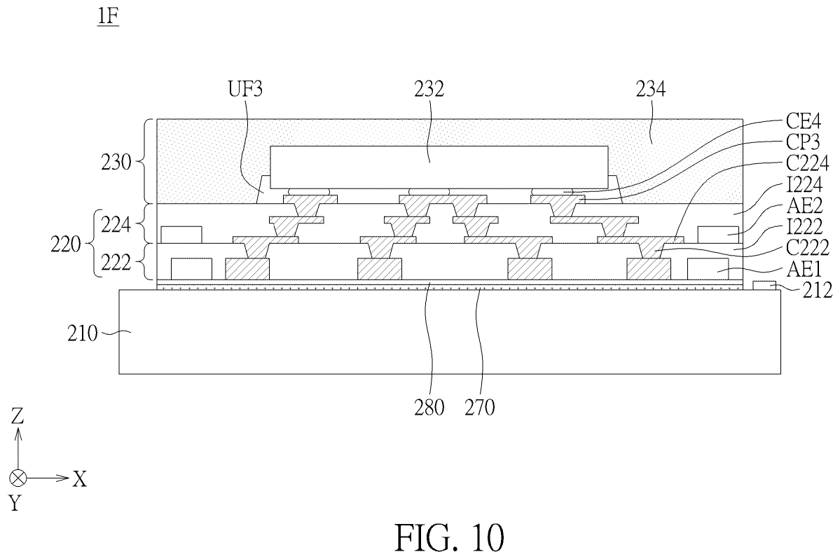

Although not shown in FIG. 1 and FIG. 2, the substructure 121A may optionally include at least one adjustment element (see the first adjustment element AE1 and the second adjustment element AE2 in FIG. 10) disposed in the insulating layer I21 to adjust the coefficient of thermal expansion of the substructure 121A, so that the overall stress of the substructure 121A may be adjusted. Similarly, the substructures 122A˜126A may also independently and optionally include at least one adjustment element. For details of the adjustment element, references may be made to the relevant description of FIG. 10.

The package structure 130A may include at least one electronic unit. Herein, the package structure 130A includes an electronic unit 132 and an electronic unit 134 as an example. The electronic unit 132 and the electronic unit 134 are electrically connected with the circuit structure 120A. Each of the electronic unit 132 and the electronic unit 134 may be a chip. The chip may be a system on chip (SoC), a dynamic random-access memory (DRAM) chip, a high bandwidth memory (HBM) chip, a photonic integrated circuit (PIC), an application-specific integrated circuit (ASIC) chip, or other logic integrated circuit chips, but not limited thereto. The chip may include an active surface having a pad (not shown) and a back surface opposite to the active surface. The pad may be an I/O pad (input/out-put pad). Herein, the chip faces the circuit structure 120A with the active surface, and the chip may be electrically connected with the circuit structure 120A through the pad on the active surface. In some embodiments, the electronic unit 132 and the electronic unit 134 may be unpackaged or known-good bare chips. In the present disclosure, the active surface may include an active element layer, such as a transistor and a related dielectric layer. The types of the electronic unit 132 and the electronic unit 134 may be the same or different.

As shown in FIG. 1, the number of electronic units 132 is eight, in which four electronic units 132 are arranged along a first horizontal direction (such as the direction Y) to form a column, and the other four electronic units 132 are arranged along the first horizontal direction to form another column. The number of electronic units 134 is two, and the two electronic units 134 are arranged along the first horizontal direction to form a column. The electronic units 132 and the electronic unit 134 are staggered along the second horizontal direction (such as the direction X). However, the present disclosure is not limited thereto. The type, the number and the arrangement of the electronic units in the package structure 130A may be adjusted according to actual needs.

The package structure 130A may optionally include a warpage adjustment layer 136. With the warpage adjustment layer 136, the coefficient of thermal expansion of the entire package structure 130A can be adjusted, and thus the overall stress of the package structure 130A can be adjusted. In FIG. 2, the warpage adjustment layer 136 partially covers the upper surface S31 of the electronic unit 132 and the upper surface S35 of the electronic unit 134. The warpage adjustment layer 136 is disposed in the gap G1 between the electronic unit 132 and the electronic unit 134 and covers the side surface S32 of the electronic unit 132 and the side surface S36 of the electronic unit 134 that are opposite to each other. The warpage adjustment layer 136 does not cover the side surface S33 of the electronic unit 132 facing outward and the side surface S37 of the electronic unit 134 facing outward. Thus, the warpage adjustment layer 136 does not completely cover the electronic unit 132 and the electronic unit 134, which is beneficial for the heat dissipation of the electronic unit 132 and the electronic unit 134, but not limited thereto. The volume of the warpage adjustment layer 136 and the range that the warpage adjustment layer covering the electronic unit 132 and the electronic unit 134 can be adjusted according to the coefficient of thermal expansion required by the package structure 130A. In the present disclosure, adjusting the coefficient of thermal expansion may include: a) adjusting the volume ratio of the elements to achieve the desired coefficient of thermal expansion; b) in addition to adjust the volume ratio of the elements, different elements in a certain structural layer have different thermal expansion trends. Specifically, the structural layer includes an element A and an element B, the element may have tensile stress and the element B may have compressive stress.

In the electronic device 1A, the package structure 130A is disposed with the warpage adjustment layer 136 as an example. The substrate structure 110A and any substructure of the circuit structure 120A may also be disposed with at least one warpage adjustment layer on the upper surface and/or the lower surface thereof according to actual needs. In other words, at least one of the substrate structure 110A, the substructure of the circuit structure 120A, and the package structure 130A may optionally include at least one warpage adjustment layer. The warpage adjustment layer may be directly contact with at least one of the substrate structure 110A, the substructure of the circuit structure 120A, and the package structure 130A. The material of the warpage adjustment layer 136 may include an organic material, an inorganic material, or a combination thereof.

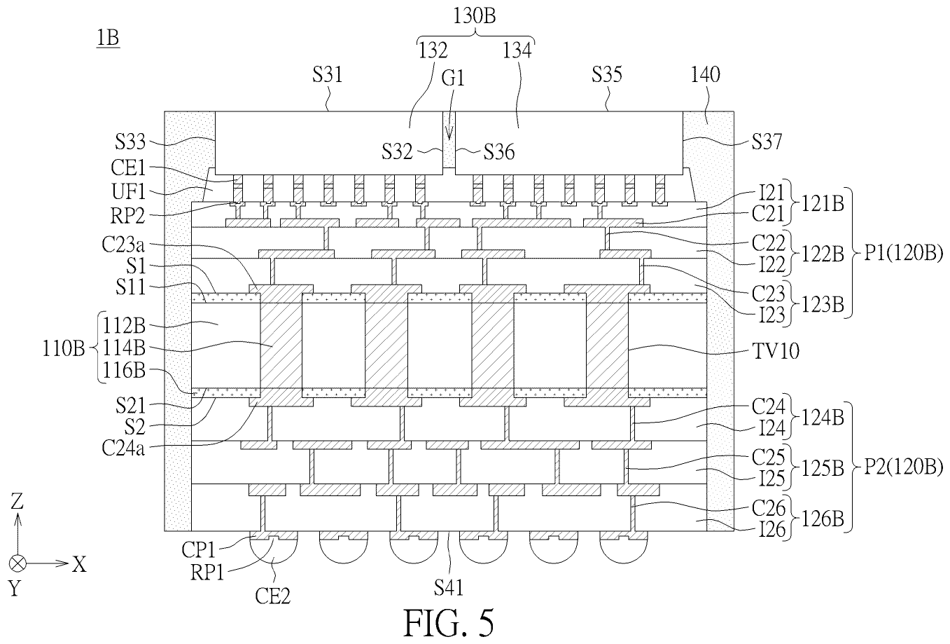

The electronic device 1A may further include a plurality of bonding elements CE1. The plurality of bonding elements CE1 are disposed between the package structure 130A and the circuit structure 120A. The package structure 130A and the circuit structure 120A may be electrically connected through the plurality of bonding elements CE1. In some embodiments, a surface of the pad C21b (see FIG. 3) facing the bonding element CE1 may be formed with a concave portion (see the concave portion RP2 in FIG. 5). Thereby, the bonding element CE1 may extend into the concave portion of the pad C21b, and the bonding strength between the bonding element CE1 and the pad C21b may be improved. The electronic device 1A may further include a filler UF1. The filler UF1 is disposed in the gaps between the plurality of bonding elements CE1. The filler UF1 may include a material with low hygroscopicity. In some embodiments, the filler UF1 may include an organic material, an inorganic material or a combination thereof. The filler UF1 can protect and fix the bonding elements CE1, so that the probability of peeling off or poor electrical connection of the bonding elements CE1 caused by the influence of moisture and/or external force can be reduced.

The electronic device 1A may further include a plurality of bonding elements CE2 disposed on the surface of the circuit structure 120A away from the package structure 130A, herein, the surface S41 of the substructure 126A away from the substrate structure 110A. Specifically, the circuit structure 120A is disposed between the substrate structure 110A and the plurality of bonding elements CE2. The circuit structure 120A can be electrically connected with other external elements (not shown) through the bonding elements CE2. Herein, the plurality of bonding elements CE2 are disposed on the surface S41 of the substructure 126A through the plurality of pads CP1 and electrically connected with the circuit structure 120A. In some embodiments, the surface of the pad CP1 facing the bonding element CE2 may be formed with a concave portion (see the concave portion RP1 in FIG. 5). Thereby, the bonding element CE2 can extend into the concave portion of the pad CP1, so that the bonding strength between the bonding element CE2 and the pad CP1 can be improved.

The bonding elements CE1 and the bonding elements CE2 may be made of a conductive material. The conductive material may include a metal, such as tin included, nickel-gold, copper or a combination thereof. The plurality of bonding elements CE1 and the bonding elements CE2 may independently be bumps, solder balls or pads. In this embodiment, a size of at least one of the plurality of bonding elements CE1 is less than a size of at least one of the plurality of bonding elements CE2. In addition, the sizes of the plurality of bonding elements CE1 may be the same, and the sizes of the plurality of bonding elements CE2 may be the same. The aforementioned “size” may refer to the maximum length of each of the bonding elements CE1 and the bonding elements CE2 in the horizontal direction (e.g., the direction X).

In the present disclosure, when a structure or a layer includes n compositions and/or elements, and n is a positive integer greater than 0, the coefficient of thermal expansion of the structure or the layer can be calculated by Formula (I):

$$α = {\sum }_{i = 1}^{n} {V}_{i} \times {α}_{i} . \qquad ( I )$$

In the above formula, a is the coefficient of thermal expansion of the structure or the layer, Vᵢ is the volume percent of the i-th composition and/or element in the structure or the layer, and αᵢ is the coefficient of thermal expansion of the i-th composition and/or element. The aforementioned “volume percent of the i-th composition and/or element in the structure or the layer” may be measured by an optical detection instrument such as an X-ray device to obtain the size or volume of the i-th composition and/or element in the structure or the layer.

Taking the substrate structure 110A as an example, the substrate structure 110A includes three elements, namely, the base layer 112A, the buffer layer 1141, and the conductive layer 1142. V₁ may be the volume percent of the base layer 112A in the substrate structure 110A, α₁ may be the coefficient of thermal expansion of the base layer 112A, V₂ may be the volume percent of the buffer layer 1141 in the substrate structure 110A, α₂ may be the coefficient of thermal expansion of the buffer layer 1141, V₃ may be the volume percent of the conductive layer 1142 in the substrate structure 110A, α₃ may be the coefficient of thermal expansion of the conductive layer 1142, and the coefficient of thermal expansion a of the substrate structure 110A is calculated as follows:

$$α = {\sum }_{i = 1}^{3} {V}_{i} \times {∝}_{i} = {V}_{1} \times {∝}_{1} + {V}_{2} \times {∝}_{2} + {V}_{3} \times {∝}_{3} .$$

The coefficients of thermal expansion of the package structure 130A, the circuit structure 120A, and each substructure can be calculated in the same manner, and are omitted herein.

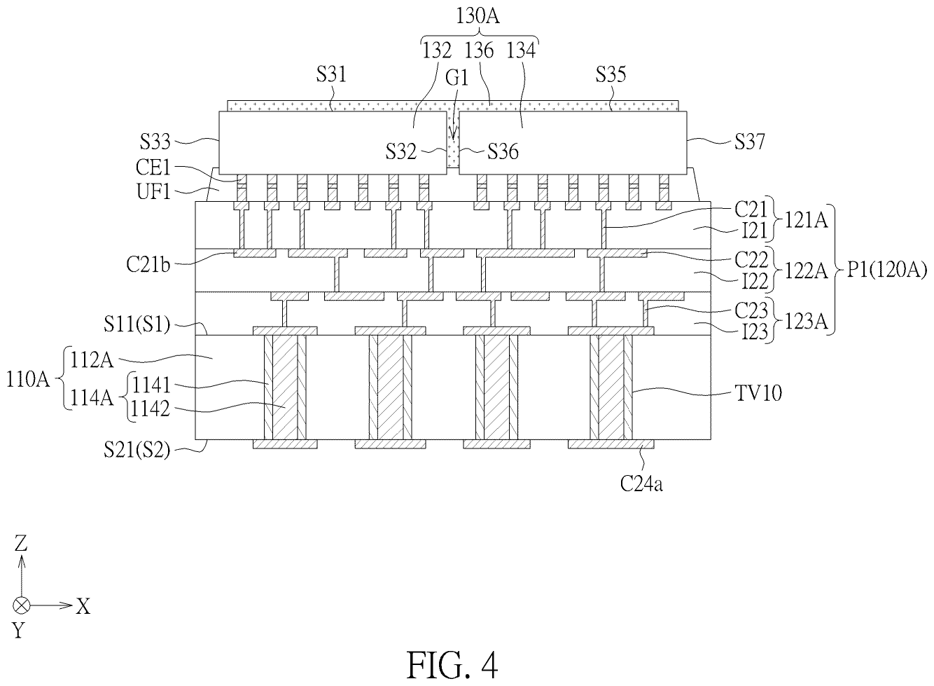

Please refer to FIG. 3 and FIG. 4, which are cross-sectional schematic diagrams showing a method for manufacturing the electronic device 1A shown in FIG. 2. As shown in FIG. 3, a substrate structure 110A is first provided, which may include steps as follows. A base layer 112A is provided, and the base layer 112A has a plurality of through holes TV10. The through holes TV10 may be formed in the base layer 112A by a laser modification process and an etching process, or may be formed in the base layer 112A by a laser drilling process.

Next, the conductive element 114A is formed in the through hole TV10. First, the buffer layer 1141 is formed. For example, a buffer material layer may be formed by an electroplating process, a chemical electroplating process, a physical vapor deposition process or other suitable processes to conformally cover the surface of the base layer 112A, including the hole wall inside the through hole TV10 and the upper surface S11 and the lower surface S21 of the base layer 112A. Next, a planarization process may be performed to remove the buffer material layer on the upper surface S11 and the lower surface S21 of the base layer 112A, and the remaining buffer material layer on the hole wall is the buffer layer 1141. Next, the conductive layer 1142 is formed. For example, a conductive material layer may be formed by an electroplating process, a chemical electroplating process, a physical vapor deposition process or other suitable processes to fill the through hole TV10, and then the conductive material layer located on the upper surface S11 and the lower surface S21 of the base layer 112A is removed by a planarization process. The remaining conductive material layer in the through hole TV10 is the conductive layer 1142.

Next, a circuit structure 120A is provided on the substrate structure 110A, which may include steps as follows. A pad C23a is formed on the surface S1 of the substrate structure 110A and a pad C24a is formed on the surface S2 of the substrate structure 110A. For example, a seed layer (not shown) may be optionally formed to blanketly cover the surface S1 and the surface S2 of the base layer 112A, and a patterned photoresist (not shown) may be formed on the seed layer to define the positions of the pad C23a and the pad C24a. The patterned photoresist has at least one opening to expose a portion of the seed layer. Next, a conductive film layer is formed on the exposed seed layer. Afterward, the patterned photoresist and the seed layer located below the patterned photoresist are removed to complete the manufacture of the pad C23a and the pad C24a. The conductive film layer may be formed through an electroplating process, a chemical electroplating process, a physical vapor deposition process or other suitable processes. In some embodiments, a conductive film layer may be directly formed to blanketly cover the surface S1 and the surface S2 of the substrate structure 110A, and then a patterning process (such as a grinding process or a photolithography process) is performed to remove a portion of the conductive film layer to obtain the pad C23a and the pad C24a.

Next, an insulating material layer is formed on the surface S1 to cover the pad C23a. The insulating material layer may be formed by a coating process, but not limited thereto. Next, at least one via TV23 is formed in the insulating material layer to expose the pad C23a below. The via TV23 may be formed through a photolithography process, but not limited thereto. Next, another seed layer (not shown) may be optionally formed to blanketly cover the insulating material layer and in the via TV23. Next, a patterned photoresist (not shown) is formed on the another seed layer to define the position of the pad C23c. The patterned photoresist has at least one opening to expose the another seed layer. Next, a conductive film layer is formed on the exposed portion of the another seed layer, and then the patterned photoresist and the another seed layer located below the patterned photoresist are removed to complete the fabrication of the connecting element C23b and the pad C23c. Next, an insulating material layer may be formed to cover the pads C23c and fill the gaps between the pads C23c, and then a planarization process, such as a chemical mechanical polishing process or a sandblasting process may be performed to expose the pads C23c from the insulating material layer, so that the fabrication of the substructure 123A is completed. The pads C23a, the connecting elements C23b and the pads C23c together form the conductive layer C23, and the aforementioned multiple insulating material layers together form the insulating layer I23. Afterwards, steps similar to the steps for manufacturing of the substructure 123A may be performed to form the vias TV22, the connecting elements C22a and the pads C22b to complete the fabrication of the substructure 122A, and to form the vias TV21, the connecting elements C21a and the pads C21b to complete the fabrication of the substructure 121A. Thus, the fabrication of the first portion P1 of the circuit structure 120A is completed. In some embodiments, the pad C21b may be subjected to an etching process or a surface treatment process to roughen the surface thereof and to form a concave portion (not shown), so that the bonding element CE1 formed later may extend into the concave portion of the pad C21b, thereby improving the bonding strength between the bonding element CE1 and the pad C21b. In the circuit structure 120A, the connecting element may serve as a vertical wire to electrically connect pads disposed at different horizontal levels in the vertical direction (e.g., the direction Z). The pad may serve as a connecting pad or as a wire that extends laterally, but not limited thereto.

Afterwards, a package structure 130A is provided on the circuit structure 120A. As shown in FIG. 4, the electronic unit 132 and the electronic unit 134 may be connected and fixed on the circuit structure 120A through the bonding elements CE1. One end of each of the bonding elements CE1 may correspond to the pad C21b in the substructure 121A, and the other end of each of the bonding elements CE1 may correspond to the pad (not shown) on the active surface of the electronic unit 132 or the electronic unit 134. Afterwards, a filler UF1 is provided to cover the bonding elements CE1. For example, the capillary phenomenon can be used to fill the filler UF1 between the substructure 121A and the electronic unit 132 and between the substructure 121A and the electronic unit 134, and fill into the gaps between the plurality of bonding elements CE1. In some embodiments, a hybrid bonding technique may be performed to form the bonding elements CE1. In this case, the filler UF1 may be replaced by a passivation layer. For example, a first passivation material layer (not shown) may be formed on the surface of the substructure 121A facing the electronic unit 132 and the electronic unit 134, and a second passivation material layer (not shown) may be formed on the active surfaces of the electronic unit 132 and the electronic unit 134 facing the substructure 121A. Vias are formed in the first passivation material layer by a photolithography process to expose the pads C21b of the substructure 121A, and vias are formed in the second passivation material layer to expose the pads (not shown) of the active surfaces of the electronic unit 132 and the electronic unit 134. Next, a conductive material is filled in the vias of the first passivation material layer and the vias of the second passivation material layer to form first sub-bonding elements and second sub-bonding elements. Next, the first sub-bonding elements and the second sub-bonding elements are aligned, and then a thermal treatment process is performed to bond the first sub-bonding elements and the second sub-bonding elements to form the bonding elements CE1. The first passivation material layer and the second passivation material layer together form a passivation layer, and the passivation layer covers the bonding elements CE1. In other words, in some embodiments, the filler UF1 may be replaced by the passivation layer. Afterwards, a warpage adjustment layer 136 is provided to partially cover the upper surface S31 of the electronic unit 132 and the upper surface S35 of the electronic unit 134 and fill into the gap G1 between the electronic unit 132 and the electronic unit 134. The warpage adjustment layer 136 may be formed by a coating process. Thus, the fabrication of the package structure 130A is completed.

Afterwards, as shown in FIG. 2, steps similar to the steps for manufacturing the substructure 123A may be performed to manufacture the substructure 124A, the substructure 125A, the substructure 126A and the pad CP1 in sequence. Thus, the fabrication of the second portion P2 of the circuit structure 120A and the pad CP1 is completed. In some embodiments, the pad CP1 may be subjected to an etching process or a surface treatment process to roughen the surface thereof and to form a concave portion (not shown), so that the bonding element CE2 formed later can extend into the concave portion of pad CP1, thereby improving the bonding strength between bonding element CE2 and pad CP1. Afterwards, the bonding element CE2 is formed on pad CP1. Thus, the fabrication of the electronic device 1A is completed.

Please refer to FIG. 5, which is a cross-sectional schematic diagram of an electronic device 1B according to another embodiment of the present disclosure. The electronic device 1B includes a substrate structure 110B, a circuit structure 120B and a package structure 130B. The circuit structure 120B is disposed on the surface S1 and the surface S2 of the substrate structure 110A. The circuit structure 120B may include at least one substructure. Herein, the circuit structure 120B includes six substructures as an example, which are the substructures 121B˜126B. The number of substructures in the circuit structure 120B may be adjusted according to actual needs. The package structure 130B is disposed on the circuit structure 120B and is electrically connected with the circuit structure 120B.

The main difference between the electronic device 1B and the electronic device 1A is that the structure of the substrate structure 110B is different from that of the substrate structure 110A, the package structure 130B is not disposed with a warpage adjustment layer, and the electronic device 1B further includes an encapsulation layer 140.

The substrate structure 110B may include a base layer 112B, conductive elements 114B, and may optionally include a warpage adjustment layer 116B. With the warpage adjustment layer 116B, the coefficient of thermal expansion of the entire substrate structure 110B may be adjusted. The base layer 112B may have through holes TV10, and the conductive elements 114B may be disposed in the through holes TV10. Herein, the conductive element 114B includes a conductive layer (not labeled) but does not include a buffer layer 1541. The number of the warpage adjustment layers 116B is two, and the two warpage adjustment layers 116B are respectively disposed on the upper surface S11 and the lower surface S21 of the base layer 112B. The thicknesses (i.e., the maximum length in the vertical direction (e.g., the direction Z)) and the two warpage adjustment layers 116B may be the same or different, and the warpage tendencies of the two warpage adjustment layers 116B may be the same or different, depending on the coefficient of thermal expansion required for the entire substrate structure 110B. In some embodiments, the number of the warpage adjustment layer 116B may be one, and the warpage adjustment layer 116B may be disposed on the upper surface S11 or the lower surface S21 of the base layer 112B.

The encapsulation layer 140 surrounds the substrate structure 110B, the circuit structure 120B and the encapsulation structure 130B. The encapsulation layer 140 fills into the gap G1 between the electronic unit 132 and the electronic unit 134, and the encapsulation layer 140 does not cover the upper surface S31 of the electronic unit 132 and the upper surface S35 of the electronic unit 134. The material of the encapsulation layer 140 may include an organic material, inorganic material or a combination thereof.

The method for manufacturing the electronic device 1B is described as follows. First, a substrate structure 110B is provided, which may include steps as follows. A base layer 112B is provided, and the base layer 112B has a plurality of through holes TV10. The method for forming the through hole TV10 may refer to the above description. Next, the conductive elements 114B are formed in the through holes TV10. For example, a conductive material layer may be formed to fill the through holes TV10 by an electroplating process, a chemical electroplating process, a physical vapor deposition process or other suitable processes, and the conductive material layer on the upper surface S11 and the lower surface S21 of the base layer 112B is removed by a planarization process. The remaining conductive material layer in the through holes TV10 are the conductive elements 114B. Next, a warpage adjustment material layer may be formed to blanketly cover the upper surface S11 and the lower surface S21 of the base layer 112B, and then a patterning process (such as a grinding process or a photolithography process) is performed to remove a portion of the warpage adjustment material layer to expose the conductive elements 114B in the through holes TV10. Thus, the fabrication of the warpage adjustment layer 116B is completed.

Next, a circuit structure 120B is provided on the substrate structure 110B and a package structure 130B is provided on the circuit structure 120B, which may refer to the relevant description of the electronic device 1A. Afterwards, an encapsulation layer 140 is provided to surround the substrate structure 110B, the circuit structure 120B and the package structure 130B and to fill into the gap G1 between the electronic unit 132 and the electronic unit 134. The encapsulation layer 140 may be formed by a molding process, but not limited thereto. In the present embodiment, the warpage adjustment layer 116B is formed first and then the pads C23a and the pads C24a of the circuit structure 120B are formed. Therefore, the pads C23a and the pads C24a are partially disposed on the conductive elements 114B and partially disposed on the warpage adjustment layer 116B.

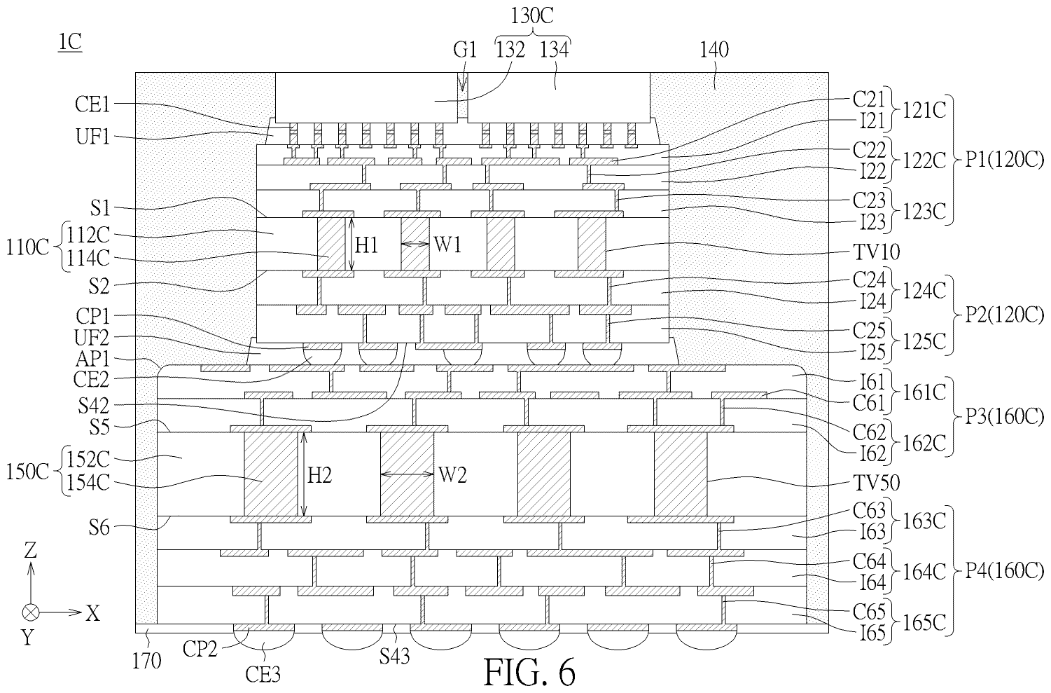

Please refer to FIG. 6, which is a cross-sectional schematic diagram of an electronic device 1C according to yet another embodiment of the present disclosure. The electronic device 1C includes a substrate structure 150C, a circuit structure 160C, a substrate structure 110C, a circuit structure 120C, and a package structure 130C.

The substrate structure 110C may include a base layer 112C and conductive elements 114C. The base layer 112C may have through holes TV10, and the conductive elements 114C may be disposed in the through holes TV10. The substrate structure 150C may include a base layer 152C and conductive elements 154C. The base layer 152C may have through holes TV50, and the conductive elements 154C may be disposed in the through holes TV50. Compared with the substrate structure 110B, the main difference of the substrate structure 110C and the substrate structure 150C is that the substrate structure 110C and the substrate structure 150C do not include a warpage adjustment layer 116B. The substrate structure 150C is farther away from the package structure 130C than the substrate structure 110C, and the size of the conductive element 154C may be larger than the size of the conductive element 114C. For example, the height H2 of the conductive element 154C may be greater than the height H1 of the conductive element 114C, and the width W2 of the conductive element 154C may be greater than the width W1 of the conductive element 114C.

The circuit structure 120C is disposed on the surface S1 and the surface S2 of the substrate structure 110C. The circuit structure 120C may include at least one substructure. Herein, the circuit structure 120C includes five substructures as an example, wherein the first portion P1 of the circuit structure 120C is disposed on the surface S1 of the substrate structure 110C and includes substructures 121C˜123C. The second portion P2 of the circuit structure 120C is disposed on the surface S2 of the substrate structure 110C and may include a substructure 124C and a substructure 125C. The number of substructures of the circuit structure 120C may be adjusted according to actual needs. The substructure 121C may include an insulating layer I21 and a conductive layer C21, and the conductive layer C21 is disposed in the insulating layer I21. The substructure may include an insulating layer and a conductive layer, and the conductive layer is disposed in the insulating layer.

The circuit structure 160C is disposed on the surface S5 and the surface S6 of the substrate structure 150C. The circuit structure 160C may include at least one substructure. Herein, the circuit structure 160C includes five substructures as an example, wherein the first portion P3 of the circuit structure 160C is disposed on the surface S5 of the substrate structure 150C and includes a substructure 161C, a substructure 162C and a substructure 163C. The second portion P4 of the circuit structure 160C is disposed on the surface S6 of the substrate structure 150C and includes a substructure 164C and a substructure 165C. The number of the substructures of the circuit structure 160C may be adjusted according to actual needs. The substructure 161C may include an insulating layer I61 and a conductive layer C61, and the conductive layer C61 is disposed in the insulating layer I61. The substructure 161C may further include an arc portion AP1 disposed at the top edge of the insulating layer I61. Thereby, it is beneficial to reduce the risk of the peeling between the substructure 161C and the encapsulation layer 140. The substructure 162C may include an insulating layer I62 and a conductive layer C62, and the conductive layer C62 is disposed in the insulating layer I62. The substructure 163C may include an insulating layer I63 and a conductive layer C63, and the conductive layer C63 is disposed in the insulating layer I63. The substructure 164C may include an insulating layer I64 and a conductive layer C64, and the conductive layer C64 is disposed in the insulating layer I64. The substructure 165C may include an insulating layer I65 and a conductive layer C65, and the conductive layer C65 is disposed in the insulating layer I65.

The package structure 130C is disposed on the circuit structure 120C and is electrically connected with the circuit structure 120C. In FIG. 6, the electronic device 1C may be an integrated fan-out package unit. The package structure 130C is disposed on the substrate structure 110C and the substrate structure 150C, and the substrate structure 110C may serve as an interposer.

The electronic device 1C may further include a plurality of bonding elements CE1, a plurality of bonding elements CE2, and a plurality of bonding elements CE3. The plurality of bonding elements CE1 are disposed between the package structure 130C and the circuit structure 120C. The package structure 130C may be electrically connected with the circuit structure 120C through the plurality of bonding elements CE1. The plurality of bonding elements CE2 are disposed between the circuit structure 120C and the circuit structure 160C. The circuit structure 120C may be electrically connected with the circuit structure 160C through the plurality of bonding elements CE2. The circuit structure 120C may further include a plurality of pads CP1 disposed on the surface S42 of the substructure 125C and electrically connected with the conductive layer C25 of the substructure 125C. The plurality of bonding elements CE2 are disposed on the surface S42 of the substructure 125C through the plurality of pads CP1 and electrically connected with the circuit structure 120C. The plurality of bonding elements CE3 are disposed on the surface of the circuit structure 160C away from the package structure 130C, herein, the surface S43 of the substructure 165C away from the substrate structure 150C. The circuit structure 160C may be electrically connected with other external elements (not shown) through the bonding elements CE3. The circuit structure 160C further includes a plurality of pads CP2 disposed on the surface S43 of the substructure 165C and electrically connected with the conductive layer C65 of the substructure 165C. The plurality of bonding elements CE3 are disposed on the surface S43 of the substructure 165C through the plurality of pads CP2 and electrically connected with the circuit structure 160C.

In the present embodiment, the size of at least one of the plurality of bonding elements CE1 is smaller than the size of at least one of the plurality of bonding elements CE2, and the size of at least one of the plurality of bonding elements CE2 is smaller than the size of at least one of the plurality of bonding elements CE3. In addition, the sizes of the plurality of bonding elements CE1 may be the same, the sizes of the plurality of bonding elements CE2 may be the same, and the sizes of the plurality of bonding elements CE3 may be the same. The aforementioned “size” may refer to the maximum length of each of the bonding elements CE1˜CE3 in the horizontal direction (e.g., the direction X). The plurality of bonding elements CE1˜CE3 may be independently the same or different. For other details about the bonding element CE3, references may be made to the relevant descriptions of the bonding elements CE1 and the bonding elements CE2 above.

The electronic device 1C may further include a filler UF1 and a filler UF2. The filler UF1 is disposed in the gaps between the plurality of bonding elements CE1. The filler UF2 is disposed in the gaps between the plurality of bonding elements CE2. The filler UF1 and the filler UF2 may be independently the same or different. For other details about the filler UF2, references may be made to the relevant description of the filler UF1 above.

The electronic device 1C may further include an encapsulation layer 140 surrounding the substrate structure 150C, the circuit structure 160C, the substrate structure 110C, the circuit structure 120C and the package structure 130C, and the encapsulation layer 140 fills into the gap G1 between the electronic unit 132 and the electronic unit 134.

The electronic device 1C may further include a protective layer 170 disposed on the lower surface of the circuit structure 160C, i.e., the surface S43 of the substructure I65C away from the substrate structure 150C. A portion of the protective layer 170 may be disposed in the gaps between the plurality of bonding elements CE3. The protective layer 170 may be configured to prevent moisture or contamination from entering the metal lines of the circuit structure 160C and may be configured to define the sizes of the bonding elements CE3. According to an embodiment, the protective layer 170 may be solder mask ink, but not limited thereto.

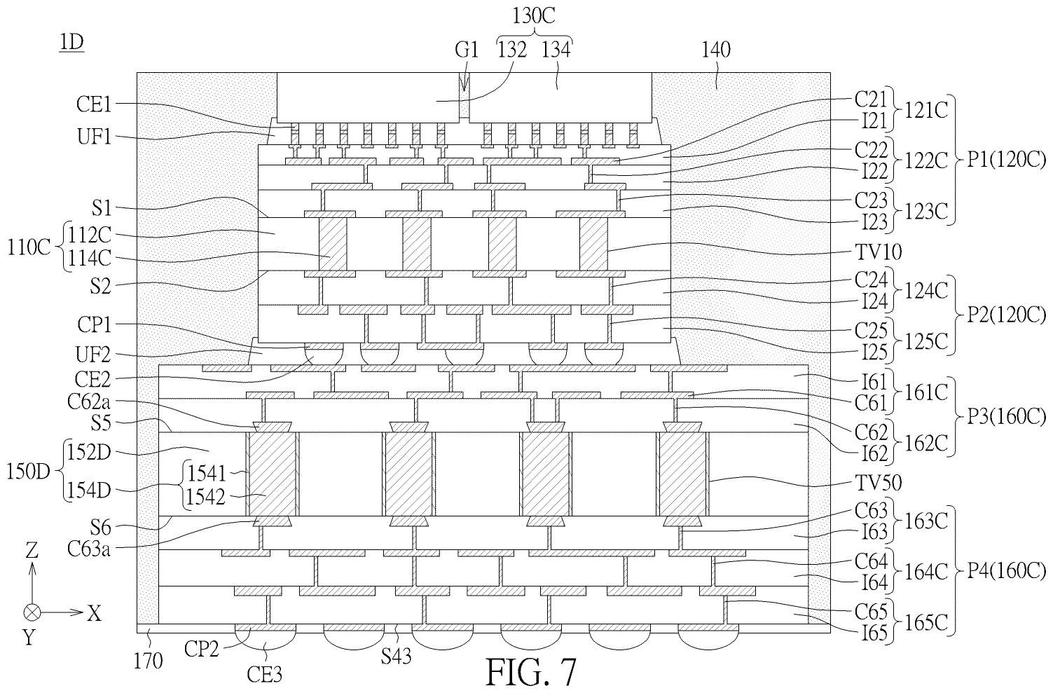

Please refer to FIG. 7, which is a cross-sectional schematic diagram of an electronic device 1D according to yet another embodiment of the present disclosure. The main differences between the electronic device 1D and the electronic device 1C are described as follows. The conductive element 154D of the substrate structure 150D may include a buffer layer 1541 and a conductive layer 1542, and the buffer layer 1541 may be disposed between the conductive layer 1542 and the base layer 152D. The pad C62a of the conductive layer C62 partially covers the upper surface of the conductive element 154D exposed from the base layer 152D, and the pad C63a of the conductive layer C63 partially covers the lower surface of the conductive element 154D exposed from the base layer 152D. For other details about the electronic device 1D, references may be made to the relevant description of the electronic device 1C above.

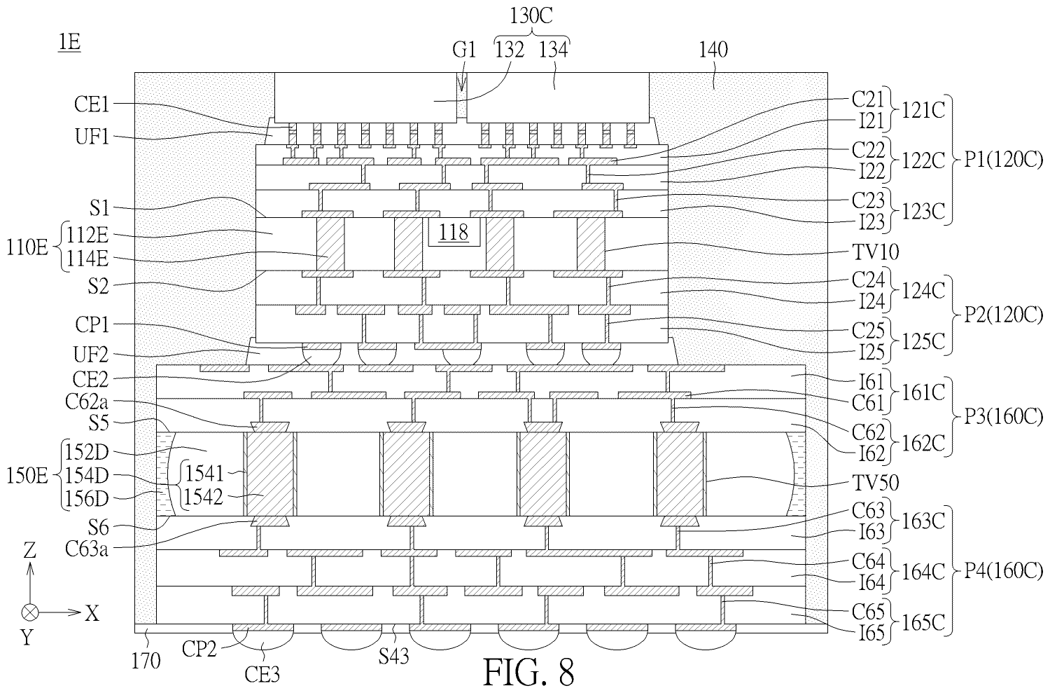

Please refer to FIG. 8, which is a cross-sectional schematic diagram of an electronic device 1E according to yet another embodiment of the present disclosure. The main difference between the electronic device 1E and the electronic device 1D is that the substrate structure 110E further includes an electronic unit 118 disposed inside the substrate structure 110E, and the substrate structure 150E further includes an anti-stress layer 156D. Specifically, the substrate structure 110E includes a base layer 112E, conductive elements 114E, and an electronic unit 118. The conductive elements 114E and the electronic unit 118 are disposed in the base layer 112E, and the base layer 112E surrounds the conductive elements 114E and the electronic unit 118. The anti-stress layer 156D and the warpage adjustment layer 270 may be the same or different. In the present disclosure, the electronic unit 118 disposed inside the substrate structure 110E may refer that the electronic unit 118 may be disposed in a recess of the base layer 112E of the substrate structure 110E, and the electronic unit 118 may be disposed inside the substrate structure 110E by a pick and place method, a surface mount technology (SMT), a thin film deposition technology, a combination thereof or other suitable methods.

The electronic unit 118 may be electrically connected with the electronic unit 132 and the electronic unit 134 through the circuit structure 120C and the bonding elements CE1. The electronic unit 118 may completely overlap or partially overlap with at least one of the electronic unit 132 and the electronic unit 134 in a vertical direction (e.g., the direction Z), which is beneficial to increase the maximum applied rate of planar space, so that the arrangement of the electronic elements in the electronic device 1E can be denser, and the current trend of miniaturization of electronic products can be satisfied. In addition, the electronic unit 118 and the electronic unit 132 and the electronic unit 134 may be connected via a wire in the vertical direction D2, which is less likely to cause signal loss and can provide a better signal transmission effect compared to be connected with a wire in the horizontal direction.

In some embodiments, the electronic unit 118 may also be an active element, such as a chip of a different type from the electronic unit 132 and the electronic unit 134, but not limited thereto.

The substrate structure 150E includes a base layer 152D, conductive elements 154D, and an anti-stress layer 156D. The conductive elements 154D are disposed in the base layer 152D, the base layer 152D surrounds the conductive elements 154D, and the anti-stress layer 156D surrounds the base layer 152D. In some embodiments, the base layer 152D may have an arc-shaped side surface, and the anti-stress layer 156D is disposed on the arc-shaped side surface of the base layer 152D. Thereby, it is beneficial to reduce the risk of the peeling between the anti-stress layer 156D and the base layer 152D. With the anti-stress layer 156D, the coefficient of thermal expansion of the entire substrate structure 150E may be adjusted, so that the overall stress of the substrate structure 150E can be adjusted to reduce the warpage degree of the substrate structure 150E. Alternatively, according to some embodiments, with the anti-stress layer 156D around the base layer 152D, the risk of cracking of the base layer 152D can be reduced, but not limited thereto.

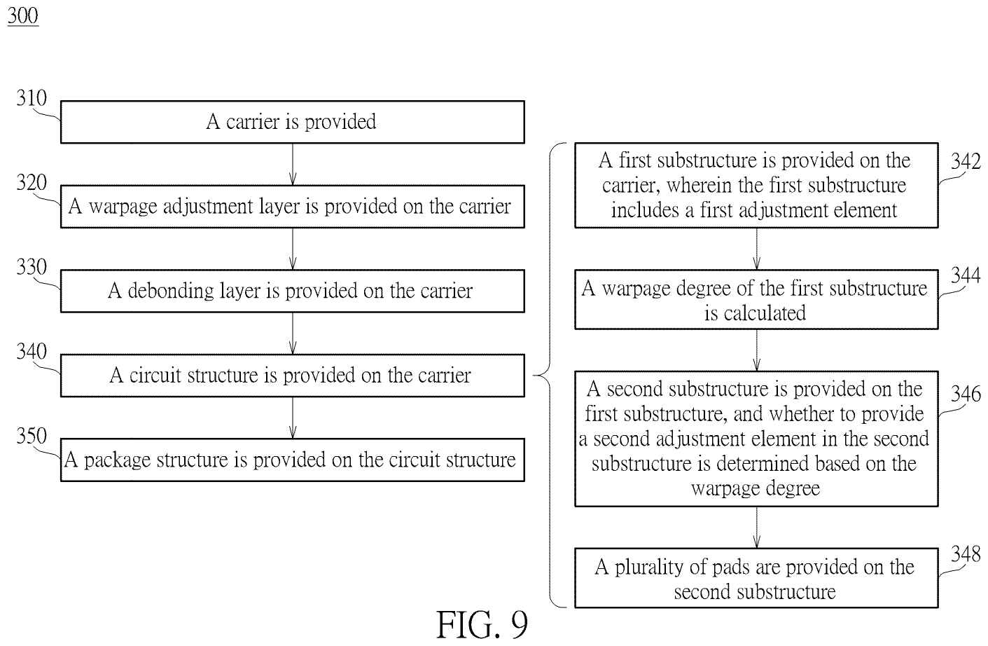

Please refer to FIG. 9 and FIG. 10. FIG. 9 is a flow chart illustrating steps of a method 300 for manufacturing an electronic device according to yet another embodiment of the present disclosure. FIG. 10 is a cross-sectional schematic diagram of an electronic device 1F according to yet another embodiment of the present disclosure. Herein, an example of manufacturing the electronic device 1F using the method 300 is described below, but not limited thereto. The method 300 according to the present disclosure may be used to manufacture other electronic devices.

The method 300 for manufacturing the electronic device includes Step 310 and Step 340, and may optionally includes Step 320, Step 330 and Step 350. In Step 310, a carrier 210 is provided. Herein, the carrier 210 is a single-layer structure as an example. In other embodiments, the carrier 210 may be a multi-layer structure. For example, the carrier 210 may be a two-layer structure or a three-layer structure. The carrier 210 may include glass, bismaleimide-triazine (BT) resin, flame retardant 4 (FR4), silicon or a combination thereof. The carrier 210 may optionally include a marking element 212. The marking element 212 may be an alignment mark element and/or a test key element, but not limited thereto. The alignment mark element may be used to assist in alignment, and can improve the alignment accuracy between different layers and reduce the pattern deviation. The test key element may be used to monitor process variation, such as detecting the warpage degree.

In Step 320, a warpage adjustment layer 270 is provided on the carrier 210. The warpage adjustment layer 270 is configured to reduce the warpage degree of the circuit structure 220 formed subsequently, and the warpage adjustment layer 270 is configured to have a warpage direction opposite to that of the circuit structure 220. For example, according to the insulating layer I222 and the insulating layer I224 of the circuit structure 220, it is known that the circuit structure 220 will warpage upwardly, so that the warpage adjustment layer 270 may be selected from a material that will warpage downwardly. That is, the warpage adjustment layer 270 may be made of a material having a warpage tendency opposite to that of the circuit structure 220. The warpage adjustment layer 270 may be a single-layer structure or a multi-layer structure (not shown), and the material of the warpage adjustment layer 270 may include an inorganic material, such as silicon oxide, silicon nitride, silicon oxynitride, other suitable materials or a combination thereof. In the present embodiment, the warpage adjustment layer 270 is disposed on the upper surface of the carrier 210, but not limited thereto. In some embodiments, the warpage adjustment layer 270 may be disposed on the lower surface of the carrier 210. In other embodiments, the number of the warpage adjustment layers 270 is two, and the two warpage adjustment layers 270 are respectively disposed on the upper surface and the lower surface of the carrier 210.

In Step 330, a debonding layer 280 is provided on the carrier 210. The debonding layer 280 may include organic materials, but not limited thereto. In some embodiments, when the carrier 210 serves as a part of the final product, the debonding layer 280 may be omitted. In this embodiment, the debonding layer 280 can be disposed above or below the warpage adjustment layer 270, which may be determined depending on whether the warpage adjustment layer 270 serves as part of the final product. When the debonding layer 280 is disposed above the warpage adjustment layer 270, and when the debonding layer 280 is separated from the circuit structure 220, the warpage adjustment layer 270 and the carrier 210 are separated from the circuit structure 220 together with the debonding layer 280. When the debonding layer 280 is disposed below the warpage adjustment layer 270, and when the debonding layer 280 is separated from the circuit structure 220, the warpage adjustment layer 270 can be retained on the circuit structure 220 and can be a part of the final product. In other words, the order of Step 320 and Step 330 can be adjusted according to actual needs.

In Step 340, a circuit structure 220 is provided on the carrier 210. Herein, the circuit structure 220 includes two substructures as an example, and the two substructures are the first substructure 222 and the second substructure 224. The circuit structure 220 may optionally further include a plurality of pads CP3 disposed on the second substructure 224.

Step 340 may include Step 342, Step 344 and Step 346, and may optionally include Step 348. In Step 342, a first substructure 222 is provided on the carrier 210, wherein the first substructure 222 includes a first adjustment element AE1. Specifically, the first substructure 222 includes an insulating layer I222, a conductive layer C222, and a first adjustment element AE1. The conductive layer C222 and the first adjustment element AE1 are disposed in the insulating layer I222, and the insulating layer I222 surrounds the conductive layer C222 and the first adjustment element AE1. With the first adjustment element AE1, the coefficient of thermal expansion of the first substructure 222 may be adjusted. In some embodiments, the first adjustment element AE1 may provide a heat dissipation function.

The first adjustment element AE1 may include silicon (Si), germanium (Ge), silicon germanium (SiGe), silicon carbide (SiC), gallium arsenide (GaAs), gallium phosphide (GaP), indium phosphide (InP), indium arsenide (InAs), indium antimonide (InSb), gallium arsenide phosphide (GaAsP), aluminum indium arsenide (AlInAs), aluminum gallium arsenide (AlGaAs), gallium indium arsenide (GaInAs), gallium indium phosphide (GaInP), gallium indium arsenide phosphide (GaInAsP), or a combination thereof, copper, any other material having a higher hardness and a lower coefficient of thermal expansion than the surrounding insulating layer (herein the insulating layer I222) or a combination thereof.

Herein, the number of the first adjustment elements AE1 is two, and the thickness of the first adjustment element AE1 is less than the thickness of the first substructure 222. In some embodiments, the number of the first adjustment elements AE1 may be equal to one or greater than two. In some embodiments, the thickness of the first adjustment element AE1 may be equal to the thickness of the first substructure 222. When the number of the first adjustment elements AE1 is plural, the materials and thicknesses of the plurality of first adjustment elements AE1 may be independently the same or different. In other words, the material, the number and the thickness of the first adjustment element AE1 may be adjusted according to actual needs.

In Step 344, a warpage degree of the first substructure 222 is calculated. The warpage degree may be calculated as follows: the warpage direction or the warpage height in the direction Z of the element is measured by an optical detection instrument. Specifically, with the X axis as the reference 0 axis, the distances between at least two edges of the element and the 0 axis are the warpage degree. In some embodiments, when the warpage degree falls within 8 mm, it means that the warpage degree is within an acceptable range, but not limited thereto.

In Step 346, a second substructure 224 is provided on the first substructure 222, and whether to provide a second adjustment element AE2 in the second substructure 224 is determined based on the warpage degree. Specifically, the second substructure 224 includes an insulating layer I224 and a conductive layer C224, and can optionally include the second adjustment element AE2 according to the warpage degree of the first substructure 222. The conductive layer C224 and the second adjustment element AE2 are disposed in the insulating layer I224, and the insulating layer I224 surrounds the conductive layer C224 and the second adjustment element AE2. For example, when the warpage degree of the first substructure 222 is within the acceptable range, it is not necessary to dispose the second adjustment element AE2 in the second substructure 224 to balance the warpage degree of the first substructure 222. When the warpage degree of the first substructure 222 falls outside the desired range, in this case, it is necessary to dispose the second adjustment element AE2 in the second substructure 224 to balance the warpage degree of the first substructure 222. In FIG. 10, the warpage degree of the first substructure 222 is outside the expected range as an example, so that the second adjustment element AE2 is disposed in the second substructure 224.

The second adjustment element AE2 may overlap or not overlap with the first adjustment element AE1 in the vertical direction (e.g., the direction Z). For the material of the second adjustment element AE2, references may be made to the relevant description of the material of the first adjustment element AE1. The first adjustment element AE1 and the second adjustment element AE2 may be independently the same or different.

Herein, the number of the second adjustment elements AE2 is two, and the thickness of the second adjustment element AE2 is less than the thickness of the second substructure 224. In some embodiments, the number of the second adjustment elements AE2 may be equal to one or greater than two. In some embodiments, the thickness of the second adjustment element AE2 may be equal to the thickness of the second substructure 224. When the number of the second adjustment elements AE2 is plural, the materials and the thicknesses of the plurality of second adjustment elements AE2 may be independently the same or different. In other words, the material, the number, and the thickness of the second adjustment element AE2 may be adjusted according to actual needs.

In some embodiments, when the number of substructures of the circuit structure 220 is greater than three, after the fabrication of the second substructure 224 is completed, the warpage degree of the second substructure 224 may be calculated. When a third substructure (not shown) is provided on the second substructure 224, and whether a third adjustment element is provided in the third substructure may be determined according to the warpage degree of the second substructure 224, and so on, till the number of substructures of the circuit structure 220 reaches the required number. As long as two adjacent substructures in the circuit structure 220 are subjected to the aforementioned steps, it is beneficial to reduce the warpage degree of the entire circuit structure 220. In other words, the method 300 for manufacturing the electronic device according to the present disclosure can monitor the warpage degree of a just-formed substructure in real time, and can determine whether to provide an adjustment element in the next substructure based on the warpage degree, so as to balance the aforementioned warpage degree in real time. When the number of substructures of the circuit structure 220 is greater than two, the risk of excessive warpage degree of the entire circuit structure 220 caused by accumulation of warpage of multiple substructures can be reduced.

In Step 348, a plurality of pads CP3 are provided on the second substructure 224. The circuit structure 220 may be electrically connected with the package structure 230 formed later through the pads CP3. In some embodiments, the pads CP3 can be manufactured simultaneously with a portion of the conductive layer C224.

In Step 350, a package structure 230 is provided on the circuit structure 220. The package structure 230 includes an electronic unit 232, a package layer 234, bonding elements CE4, and a filler UF3. The electronic unit 232 is disposed on the circuit structure 220 and is electrically connected with the circuit structure 220 through the bonding elements CE4. The filler UF3 is disposed in the gaps between the plurality of bonding elements CE1 and the gaps between the plurality of pads CP3. The encapsulation layer 234 covers the electronic unit 232 and the filler UF3. Herein, the encapsulation layer 234 covers and surrounds the electronic unit 232 and the filler UF3, and the encapsulation layer 234 covers the surface of the second substructure 224 that is not covered by the filler UF3.

The ratio of the coefficient of thermal expansion of the package structure 230 to the coefficient of thermal expansion of at least one of the first substructure 222 and the second substructure 224 is greater than or equal to 0.8 and less than or equal to 1.5. The coefficient of thermal expansion of the package structure 230 can be together determined by the electronic unit 232, the encapsulation layer 234, the bonding elements CE4 and the filler UF3. The coefficient of thermal expansion of the first substructure 222 can be together determined by the insulating layer I222, the conductive layer C222 and the first adjustment element AE1. The coefficient of thermal expansion of the second substructure 224 can be together determined by the insulating layer I224, the conductive layer C224 and the second adjustment element AE2. The coefficient of thermal expansion can be calculated according to the above Formula (I), and is not repeated herein.

Specifically, after the fabrication of the circuit structure 220 is completed, the coefficient of thermal expansion of the first substructure 222 and/or the second substructure 224 can be calculated based on the compositions and/or elements included in the first substructure 222 and/or the second substructure 224, and then the proportion of each composition and/or element in the package structure 230 can be determined, so that the ratio of the coefficient of thermal expansion of the package structure 230 to the coefficient of thermal expansion of at least one of the first substructure 222 and the second substructure 224 can satisfy the aforementioned relationship, which is beneficial to improve the matching degree of the coefficient of thermal expansion of the package structure 230 and the coefficient of thermal expansion of the circuit structure 220.

The method 300 can be applied to manufacture any of the electronic device 1A, the electronic device 1B, the electronic device 1C, the electronic device 1D and the electronic device 1E. That is, any substructure of the circuit structure of any of the electronic device 1A, the electronic device 1B, the electronic device 1C, the electronic device 1D or the electronic device 1E may optionally include an adjustment element. Taking the method 300 being applied to manufacture the electronic device 1A as an example, in Step 310, the carrier 210 in FIG. 10 may be replaced by the substrate structure 110A, and Step 320 and Step 330 may be omitted. That is, the substrate structure 110A may be a part of the final product (i.e., the electronic device 1A). In Step 340, the circuit structure 220 may be replaced by the first portion P1 of the circuit structure 120A. In Step 350, the package structure 230 in FIG. 10 may be replaced by the package structure 130A. Afterward, the semi-finished product of the electronic device 1F may be turned over to continue the manufacture of the second portion P2 of the circuit structure 220. The second portion P2 of the circuit structure 120A may be manufactured by steps similar to Step 342 to Step 346.

Based on the forgoing description, in the electronic device according to the present disclosure, it is beneficial to improve the matching degree of the coefficients of thermal expansion of the package structure and the circuit structure with the ratio of the coefficient of thermal expansion of the package structure to the coefficient of thermal expansion of at least one substructure of the circuit structure being greater than or equal to 0.8 and less than or equal to 1.5. Accordingly, it is beneficial to reduce the warpage degree of the electronic device. The method for manufacturing the electronic device according to the present disclosure can monitor the warpage degree of a just-formed substructure in real time, and can determine whether to provide an adjustment element in the next substructure based on the warpage degree, so as to balance the aforementioned warpage degree in real time. When the number of substructures of the circuit structure is greater than two, the risk of excessive warpage degree of the entire circuit structure caused by accumulation of warpage of multiple substructures can be reduced.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a first substrate structure;
a first circuit structure disposed on a surface of the first substrate structure, wherein the first circuit structure comprises a first substructure; and
a package structure disposed on the first circuit structure and electrically connected with the first circuit structure;
wherein the first substructure has a first coefficient of thermal expansion, the package structure has a second coefficient of thermal expansion, and a ratio of the second coefficient of thermal expansion to the first coefficient of thermal expansion is greater than or equal to 0.8 and less than or equal to 1.5.

2. The electronic device of claim 1, wherein the first substrate structure has a third coefficient of thermal expansion, and a ratio of the second coefficient of thermal expansion to the third coefficient of thermal expansion is greater than or equal to 0.8 and less than or equal to 1.5.

3. The electronic device of claim 1, wherein at least one of the first substrate structure, the first substructure and the package structure further comprises at least one warpage adjustment layer.

4. The electronic device of claim 1, wherein the first substrate structure comprises a base layer and a conductive element, the base layer has a through hole, and the conductive element is disposed in the through hole.

5. The electronic device of claim 4, wherein the conductive element comprises a buffer layer and a conductive layer, and the buffer layer is disposed between the conductive layer and the base layer.

6. The electronic device of claim 1, wherein the first substructure comprises a first insulating layer and a first conductive layer, and the first conductive layer is disposed in the first insulating layer.

7. The electronic device of claim 6, wherein in the first substructure, a content of the first conductive layer ranges from 2 volume percent (vol %) to 55 volume percent.

8. The electronic device of claim 6, wherein the first substructure further comprises a first adjustment element, and the first adjustment element is disposed in the first insulating layer.

9. The electronic device of claim 1, wherein the package structure comprises a first electronic unit, and the first electronic unit is electrically connected with the first circuit structure.

10. The electronic device of claim 1, wherein the first substrate structure comprises a second electronic unit disposed inside the first substrate structure.

11. The electronic device of claim 1, wherein the first circuit structure further comprises a second substructure, the second substructure and the first substructure are disposed on a same side of the first substrate structure, the second substructure has a fourth coefficient of thermal expansion, and a ratio of the second coefficient of thermal expansion to the fourth coefficient of thermal expansion is greater than or equal to 0.8 and less than or equal to 1.5.

12. The electronic device of claim 1, wherein the first circuit structure further comprises a second substructure, the second substructure and the first substructure are disposed on opposite two sides of the first substrate structure, the second substructure has a fourth coefficient of thermal expansion, and a ratio of the second coefficient of thermal expansion to the fourth coefficient of thermal expansion is greater than or equal to 0.8 and less than or equal to 1.5.

13. The electronic device of claim 12, further comprising:
a plurality of bonding elements, wherein the second substructure is disposed between the substrate structure and the plurality of bonding elements.

14. The electronic device of claim 12, further comprising:
a protective layer disposed on a surface of the second substructure away from the first substrate structure.

15. The electronic device of claim 1, further comprising:
a second substrate structure; and
a second circuit structure disposed on a surface of the second substrate structure, wherein the second circuit structure is electrically connected with the first circuit structure.

16. The electronic device of claim 15, further comprising:
a plurality of bonding elements disposed between the first circuit structure and the second circuit structure, wherein the first circuit structure is electrically connected with the second circuit structure through the plurality of bonding elements.

17. A method for manufacturing an electronic device, comprising:
providing a carrier; and
providing a circuit structure on the carrier, comprising:
providing a first substructure on the carrier, wherein the first substructure comprises a first adjustment element;
calculating a warpage degree of the first substructure; and
providing a second substructure on the first substructure, and determining whether to provide a second adjustment element in the second substructure based on the warpage degree.

18. The method for manufacturing the electronic device of claim 17, further comprising:
providing a warpage adjustment layer on the carrier.

19. The method for manufacturing the electronic device of claim 17, further comprising:
providing a debonding layer on the carrier.

20. The method for manufacturing the electronic device of claim 17, further comprising:
providing a package structure on the circuit structure.
